(19) United States
(12) Patent Application Publication
(10) Pub. No.: US 2010/0283111 A1
(43) Pub. Date: Nov. 11, 2010

(54) Photo detector

(76) Inventors: Wen-Long Chou, Chunan Jenn (TW); Ni-Tang Chu, Chunan Jenn (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/453,320

(22) Filed: May 7, 2009

(51) Int. Cl. H01L 31/0232

(52) U.S. Cl. 257/432; 257/E31.127

(57) ABSTRACT

Disclosed is an improved photo detector, which includes a substrate, a light reception chip, and a coating layer. The substrate includes a first electrode member and a second electrode member. The light reception chip is set on the substrate and is electrically connected to the first and second electrode members of the substrate. The coating layer is formed on the light reception chip and functions to filter out visible light and allows only invisible light to transmit therethrough. As such, efficacies of receiving only visible light and minimizing the overall size can be realized.

### FIELD OF THE INVENTION

The present invention relates to an improved photo detector, and in particular to a photo detector that realizes reception of only invisible light and reduction of overall size through a coating layer formed thereon.

### BACKGROUND OF THE INVENTION

Light reception chips used in photo detectors can receive both visible lights and invisible lights. FIG. 3 of the attached drawings illustrates a response spectrum of a light reception chip of a conventional photo detector, in which the horizontal axis (abscissa) indicates wavelength (nm; nanometers) and the vertical axis (ordinate) is optic response ratio (%). The wavelength of the visible light is between 400 nm and 700 nm, and that of the invisible light is either less than 400 nm or greater than 700 nm. The response spectrum shown in FIG. 3 includes both visible light and invisible light, meaning the conventional photo detector, due to the inherent constraints of the light reception chip in respect of light detection, can receive both visible light and invisible light, leading to incorrect result of detection. This is the first drawback of the conventional photo detector. In order to make it possible for photo detectors to receive only invisible light, or to receive only visible light, various ways have been adopted by different manufacturers of photo detectors in order to achieve such a goal.

FIG. 1 of the attached drawings shows a conventional photo detector 1, which comprises a first lead frame 11 that forms a carrier 111, a second lead frame 12, a light reception chip 13 arranged on the carrier 111, a first conductive lead 14 electrically connecting between the first lead frame 11 and the light reception chip 13, a second conductive lead 15 electrically connecting between the second lead frame 12 and the light reception chip 13, and a package body of resin 16 covering the carrier 111, the light reception chip 13, and the first and second leads 14, 15.

Referring to FIG. 2, another conventional photo detector 2 is shown, comprising a base 20, a first lead frame 21 extending from one side of the base 20 and forming a carrier 211, a second lead frame 22 extending from an opposite side of the base 20, a light reception chip 23 arranged on the carrier 211, a first conductive lead 24 electrically connecting between the first lead frame 21 and the light reception chip 23, a second conductive lead 25 electrically connecting between the second lead frame 22 and the light reception chip 23, and a package body of resin 26 covering an upper portion of the base 20, the carrier 211, the light reception chip 23, and the first and second leads 24, 25.

The conventional photo detectors 1, 2 of the first and second types mentioned above use a package body of resin 16, 26 to alleviate the first drawback discussed above. However, the use of the package body of resin 16, 26 adversely makes the conventional photo detectors 1, 2 of the first and second types bulky and expensive, which is the second drawback.

In addition, the conventional photo detectors 1, 2 of the first and second types more severely suffer size bulkiness and high expense due to the use of first and second lead frames 11, 12, 21, 22. This is simply because of the size (length) of the lead frames themselves and is also due to the fact that although the second type of the conventional photo detector 2 has first and second lead frames 21, 22 that are shorter than the first and second lead frames 11, 12 of the first type of the conventional photo detector 1, yet a base 20 is additionally arranged. In order to provide adequate bonding strength with the lead frames 21, 22, the base 20 cannot be minimized in the thickness thereof.

Further, due to the drawback of bulkiness, the conventional photo detectors 1, 2 of the first and second types do not meet the current trend of being light-weighted and compact. In other words, due to the bulkiness of the conventional photo detector 1, 2 of the above mentioned first and second types, electronic devices that incorporate photo detectors cannot be made light-weighted and compact.

Thus, the present invention aims to provide an improved photo detector that overcomes the above discussed drawbacks of the known photo detectors and is made light-weighted and compact.

### SUMMARY OF THE INVENTION

An objective of the present invention is to provide an improved photo detector that comprises a construction having a coating layer formed on a light reception chip coated and free of packaging resin (also being free of lead frames, if necessary), so as to realize the efficacies of receiving only invisible light, reducing overall size (and further reducing the size by eliminating lead frames), and lowering costs to thereby meet the needs of the current trends of being light-weighted and compact.

To achieve the above objective, the present invention provides an improved photo detector, which comprises a substrate, a light reception chip, and a coating layer. The substrate comprises a first electrode member and a second electrode member. The light reception chip is set on the substrate and is electrically connected to the first and second electrode members of the substrate. The coating layer is formed on the light reception chip and functions to filter out visible light and allows only invisible light to transmit therethrough.

As such, the efficacies of receiving only invisible light, reducing the overall size, and lowering costs can be realized through the photo detector of the present invention and the needs of the current trend of being light-weighted and compact are met.

### BRIEF DESCRIPTION OF THE DRAWINGS

The present invention will be apparent to those skilled in the art by reading the following description of preferred embodiments thereof with reference to the drawings, in which:

FIG. 1 is a cross-sectional view of a first conventional photo detector;

FIG. 2 is a cross-sectional view of a second conventional photo detector;

FIG. 3 shows a response spectrum of a conventional photo detector;

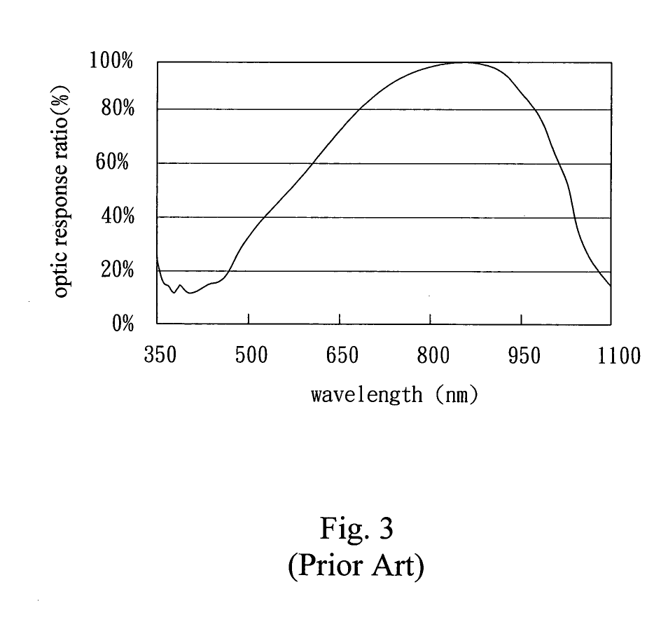

FIG. 4 is a cross-sectional view showing a photo detector constructed in accordance with a first embodiment of the present invention;

FIG. 5 is a cross-sectional view showing a photo detector constructed in accordance with a first embodiment of the present invention; and

FIG. 6 shows a response spectrum of a photo detector in accordance with the present invention.

### DETAILED DESCRIPTION OF THE PREFERRED EMBODIMENTS

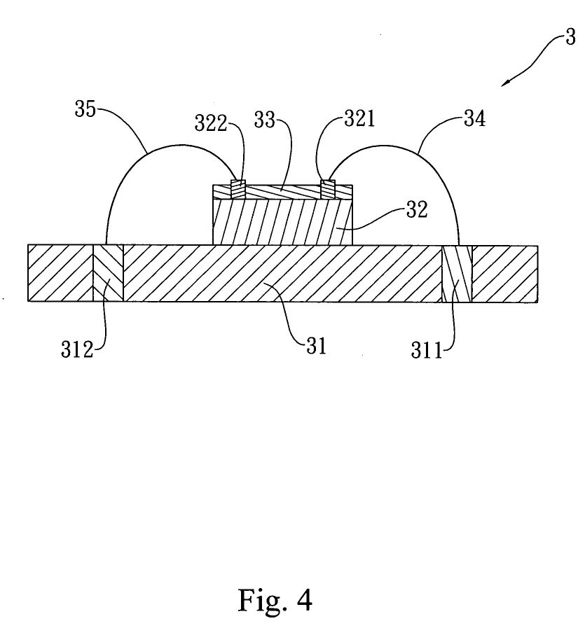

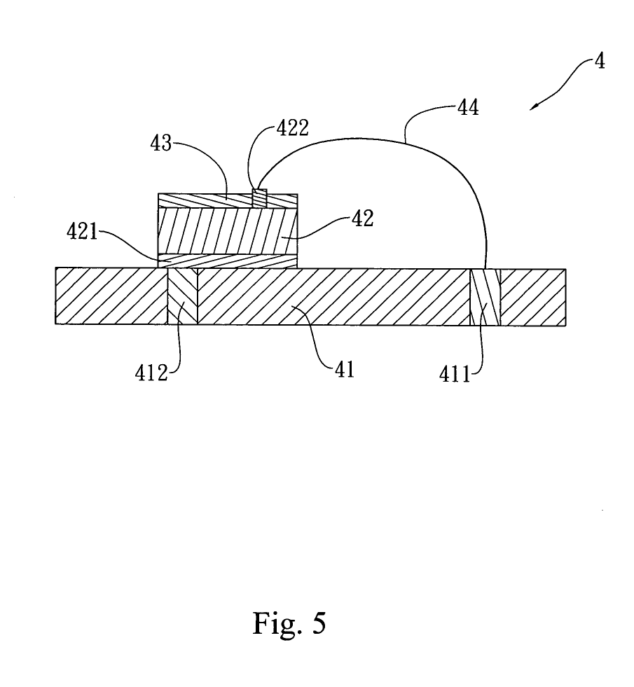

The present invention provides an improved photo detector, which makes a breakthrough of the conventional constructions of photo detectors to realize reception of only invisible light and minimization of the overall size. FIG. 4 shows a photo detector, generally designated at 3, in accordance with a first embodiment of the present invention and FIG. 5 shows a photo detector, generally designated at 4, in accordance with a second embodiment of the present invention.

Referring to FIG. 4, the photo detector 3 in accordance with the first embodiment of the present invention comprises a substrate 31, a light reception chip 32, and a coating layer 33. The substrate 31 comprises a first electrode member 311 and a second electrode member 312. The light reception chip 32 is set on the substrate 31 and the light reception chip 32 is electrically connected to the first and second electrode members 311, 312. The first and second electrode members 311, 312 are electrically connectable to external electronic parts/device and/or other electronic products from an underside of the substrate 31. The coating layer 33 is formed on the light reception chip 32. The coating layer 33 functions to filter out visible light and allows only invisible light to transmit therethrough. In other words, the light reception chip 32 only receives invisible light.

Reference is further made to the first embodiment of the present invention shown in FIG. 4. The electrical connection between the light reception chip 32 and the substrate 31 comprises a first conductive lead 34 and a second conductive lead 35. The first lead 34 electrically connects between a first electrode 321 of the light reception chip 32 and the first electrode member 311 of the substrate 31. The second lead 35 electrically connects between a second electrode 322 of the light reception chip 32 and the second electrode member 312 of the substrate 31.

Reference is made to the second embodiment of the present invention shown in FIG. 5, which is substantially identical to the first embodiment, with only difference residing on the electrical connection between a light reception chip 42 and a substrate 41. As shown, the photo detector 4 in accordance with the second embodiment of the present invention comprises a substrate 41, a light reception chip 42, and a coating layer 43. The substrate 41 comprises a first electrode member 411 and a second electrode member 412. The light reception chip 42 is set on the substrate 41 and the light reception chip 42 is electrically connected to the first and second electrode members 411, 412. The first and second electrode members 411, 412 are electrically connectable to external electronic parts/device and/or other electronic products from an underside of the substrate 41. The coating layer 43 is formed on the light reception chip 42. The coating layer 43 functions to filter out visible light, allowing only invisible light to transmit therethrough, whereby the light reception chip 42 only receives invisible light.

In the second embodiment of the present invention, the electrical connection between the light reception chip 42 and the substrate 41 (as shown in FIG. 5) comprises a conductive lead 44 and an electrical contact 421. The lead 44 electrically connects between an electrode 422 of the light reception chip 42 and the first electrode member 411 of the substrate 41. The electrical contact 45 is formed on an underside of the light reception chip 42 whereby the light reception chip 42 is set in electrically connection with the second electrode member 412 of the substrate 41 through the electrical contact 421 formed on the underside thereof.

The coating layer 33, 43 of the first and second embodiments of the present invention is made of for example a layer of metal materials, a layer of polymer materials, a layer of dielectric materials, a layer of compound materials, or a stack of multiple layers of these materials. The layer of compound materials may comprise a layer of titanium nitride (TiN), a layer of indium tin oxide (ITO), a layer zinc oxide (ZnO), or a layer of titanium dioxide (TiO₂), or a stack of multiple layers of these materials.

The substrate 31, 41 of the first and second embodiments of the present invention may comprise a circuit board on which the light reception chip 32, 42 is mounted. In other words, the light reception chip 32, 42 can be electrically connected to circuit pattern (not shown) formed on the circuit board in accordance with the first and second embodiments discussed above.

In addition, if desired, a package body of resin (not shown) can be additionally provided on the substrate 31, 41 for protection purposes (such as protecting the light reception chip 32, 42, the coating layer 33, 43, the first lead 34, 44, and the second lead 35, 45 and so on) or for other purposes. Although not shown in the drawings, the package body of resin may cover the substrate 31, 41, the light reception chip 32, 42, the coating layer 33, 43, the first lead 34, 44, and the second lead 34, 45 and the resin is one that allows light to transmit therethrough or one that filters out visible light and allows only invisible light to transmit therethrough.

The photo detector 3, 4 of the present invention offers the following advantages:

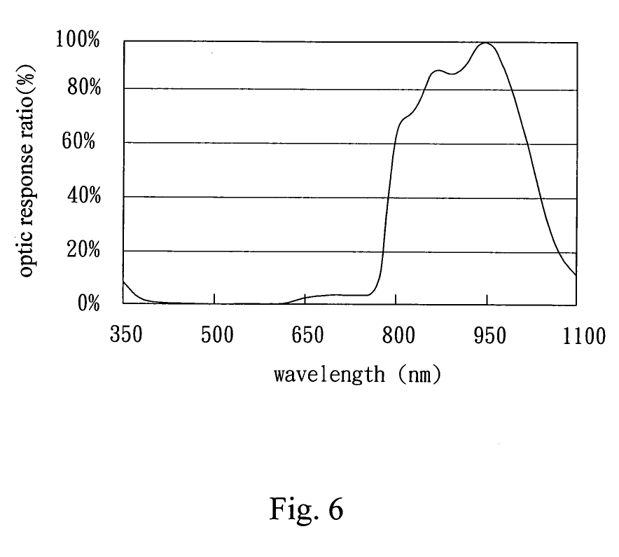

(1) With the coating layer 33, 43 formed on the light reception chip 32, 42, visible light can be filtered out by the coating layer 33, 43 and only invisible light is allowed to transmit therethrough, whereby the photo detector 3, 4 of the present invention can provide the efficacy of receiving only invisible light (as demonstrated in FIG. 6).

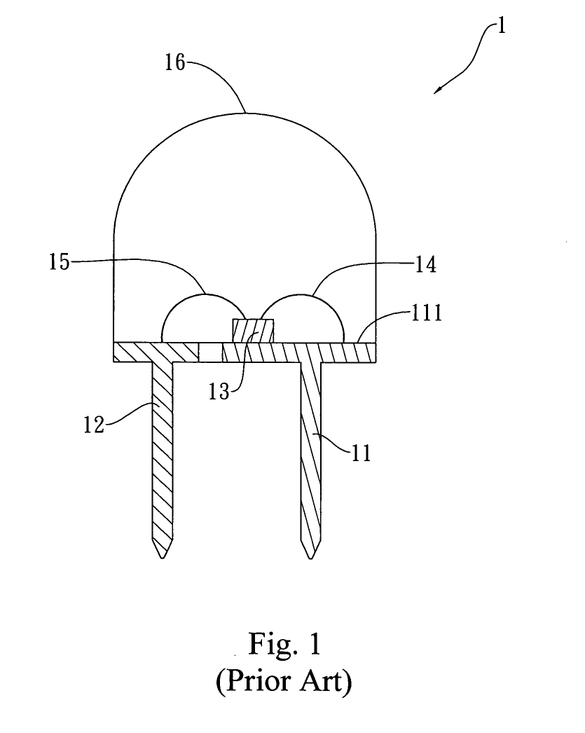

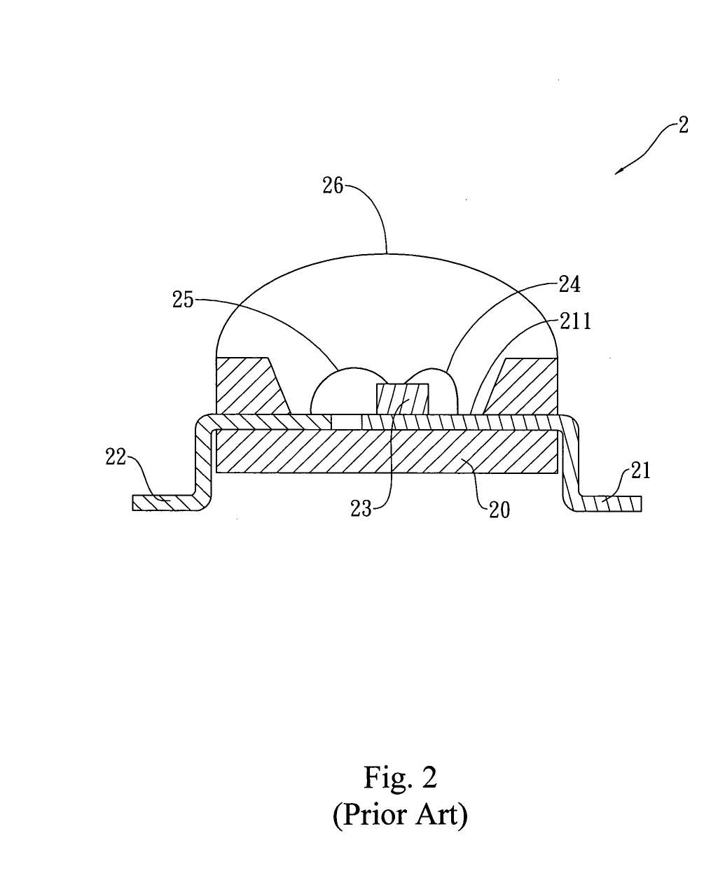

(2) With the resin-free construction in accordance with the present invention, the photo detector 3, 4 of the present invention has an overall size smaller than the conventional photo detectors 1, 2 of the first and second types discussed above (see FIGS. 1 and 2). It is apparent that besides being resin-free, the present invention can also be made free of lead frames in order to make the overall size of the photo detector 3, 4 of the present invention further smaller than the conventional photo detectors 1, 2 of the first and second types discussed above (see FIGS. 1 and 2). This is simply because of the elimination of the length of the lead frames. Another reason is that the substrate 31, 41 does not need to bond to any lead frame and thus the thickness of the substrate 31, 41 can be minimized for there is no need to concern about bonding strength, whereby the thickness of the substrate 31, 41 can be made much smaller than the thickness of the base 20 of the conventional photo detector 2 of the second type (see FIG. 2). In other words, the photo detector 3, 4 of the present invention can have an overall size that is minimized and the costs can be reduced to meet the needs of current trend of being light-weighted and compact and thus, the thickness of electronic devices can be made thinner and lighter.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. An improved photo detector, comprising:
a substrate, which comprises a first electrode member and a second electrode member;
a light reception chip, which is set on the substrate and is electrically connected to the first and second electrode members of the substrate; and
a coating layer, which is formed on the light reception chip and functions to filter out visible light and allowing only invisible light to transmit therethrough.

2. The improved photo detector as claimed in claim 1, wherein an electrical contact is provided on a side of the light reception chip adjoining the substrate, the electrical contact being in engagement with one of the first and second electrode members of the substrate, and wherein a conductive lead electrically connects between the light reception chip and another one of the first and second electrode members of the substrate.

3. The improved photo detector as claimed in claim 1, wherein a first conductive lead electrically connects between the light reception chip and one of the first and second electrode members of the substrate and wherein a second conductive lead electrically connects between the light reception chip and another one of the first and second electrode members of the substrate.

4. The improved photo detector as claimed in claim 1, wherein the coating layer selectively comprises any one of a layer of metal materials, a layer of polymer materials, a layer of dielectric materials, and a layer of compound materials.

5. The improved photo detector as claimed in claim 4, wherein the layer of compound materials selectively comprises any one of a layer of titanium nitride (TiN), a layer of indium tin oxide (ITO), a layer zinc oxide (ZnO), and a layer of titanium dioxide (TiO₂).

6. The improved photo detector as claimed in claim 4, wherein the layer of compound materials selectively comprises a stack of multiple ones of a layer of titanium nitride (TiN), a layer of indium tin oxide (ITO), a layer zinc oxide (ZnO), and a layer of titanium dioxide (TiO₂).

7. The improved photo detector as claimed in claim 1, wherein the coating layer selectively comprises a stack of multiple ones of a layer of metal materials, a layer of polymer materials, a layer of dielectric materials, and a layer of compound materials.

8. The improved photo detector as claimed in claim 7, wherein the layer of compound materials selectively comprises any one of a layer of titanium nitride (TiN), a layer of indium tin oxide (ITO), a layer zinc oxide (ZnO), and a layer of titanium dioxide (TiO₂).

9. The improved photo detector as claimed in claim 7, wherein the layer of compound materials selectively comprises a stack of multiple ones of a layer of titanium nitride (TiN), a layer of indium tin oxide (ITO), a layer zinc oxide (ZnO), and a layer of titanium dioxide (TiO₂).

10. The improved photo detector as claimed in claim 1, wherein the substrate comprises a circuit board and wherein the light reception chip is mounted on the circuit board.

11. The improved photo detector as claimed in claim 1, wherein the substrate further comprises a package body of resin covering the substrate, the light reception chip, the first electrode member, and the second electrode member, the resin of the package body comprising a resin that allows light to transmit therethrough.

12. The improved photo detector as claimed in claim 1, wherein the substrate further comprises a package body of resin covering the substrate, the light reception chip, the first electrode member, and the second electrode member, the resin of the package body comprising a resin that filter outs visible light and allows only invisible light to transmit therethrough.
